(19) United States
(12) Patent Application Publication
(10) Pub. No.: US 2021/0407837 A1
(43) Pub. Date: Dec. 30, 2021

(54) ROBOT APPARATUS AND SYSTEMS, AND METHODS FOR TRANSPORTING SUBSTRATES IN ELECTRONIC DEVICE MANUFACTURING

(71) Applicant: Applied Materials, Inc., Santa Clara, CA (US)

(72) Inventor: Jeffrey C. Hudgens, San Francisco, CA (US)

(21) Appl. No.: 17/358,384

(22) Filed: Jun. 25, 2021

Related U.S. Application Data
(60) Provisional application No. 63/046,306, filed on Jun. 30, 2020.

(51) Int. Cl. H01L 21/677; B25J 9/04; B25J 15/00; H01L 21/687

(52) U.S. Cl. CPC H01L 21/67742; B25J 9/043; B25J 15/0014; H01L 21/67167; H01L 21/67754; H01L 21/67781; H01L 21/68707

(57) ABSTRACT

Electronic device manufacturing systems, robot apparatus and associated methods are described. The systems, apparatus and methods are configured to efficiently retrieve and place substrates from N substrate supports (where N>2). The robot apparatus includes at least N end effectors plus one end effector (N+1) or plus two end effectors (N+2) enabling the robot to sequentially retrieve and place substrates within one or more process chambers during a single cycle (e.g., without having to return to a load lock or other location to place proceed substrates and retrieve unprocessed substrates).

### FIELD

The present disclosure relates to electronic device manufacturing, and more specifically to an apparatus and methods adapted to transport multiple substrates within an electronic device manufacturing apparatus.

### BACKGROUND

Conventional electronic device manufacturing systems can include multiple chambers, such as process chambers and load lock chambers. Such chambers can be included in a cluster tool where a plurality of such process and load lock chambers are distributed about a transfer chamber. Such chambers alternatively can be included in a linear tool where a plurality of such process and load lock chambers are distributed about a rectangular transfer chamber.

Such electronic device manufacturing systems can employ a robot apparatus in the transfer chamber that is configured to transport substrates between the various load lock and process chambers. In some embodiments, the transfer chamber, process chambers, and load lock chambers may operate under a vacuum at certain times. However, in certain configurations of electronic device manufacturing systems, transport of substrates between the various chambers with the robot apparatus can be inefficient, and can involve repeat trips of a robot arm between a load lock and a processing chamber.

Accordingly, an improved robot apparatus, electronic device manufacturing apparatus, and methods for transporting substrates having improved efficiency are sought.

### SUMMARY

Disclosed herein according to various embodiments are systems, comprising: one or more process chambers collectively or individually comprising N substrate supports, wherein N is an integer greater or equal to 2; at least one load lock; and a robot apparatus configured to transport substrates between the at least one load lock and the at least one process chamber, the robot apparatus comprising at least N+1 end effectors configured to transport the substrates.

According to embodiments, disclose herein are systems, comprising: at least one process chamber comprising a plurality of substrate supports, wherein the total number of substrate supports within the at least one process chamber is N, wherein N is an even integer greater or equal to 2; at least one load lock; and a robot apparatus configured to transport substrates between the at least one load lock and the at least one process chamber, the robot apparatus comprising at least N+2 end effectors configured to transport the substrates.

In yet further embodiments, disclose herein are systems, comprising: at least one process chamber comprising at least one substrate support; at least one via comprising at least one substrate support, wherein the total number of substrate supports collectively within the at least one process chamber and the at least one via is N, wherein N is an integer greater or equal to 2; at least one load lock; and a robot apparatus configured to transport substrates between the at least one load lock, the at least one process chamber and the at least one via, the robot apparatus comprising at least N+1 or at least N+2 end effectors configured to transport the substrates.

According to embodiments, disclosed herein are methods of transporting substrates by a robot apparatus, comprising: retrieving from a first substrate support, by a first end effector, a first substrate on the first end effector, wherein the first end effector is attached to the robot apparatus; placing, by a second end effector, a second substrate onto the first substrate support, wherein the second end effector is attached to the robot apparatus; retrieving from a second substrate support, by the second end effector, a third substrate on the second end effector; placing, by a third end effector, a fourth substrate onto the second substrate support, wherein the third end effector is attached to the robot apparatus; retrieving from a third substrate support, by the third end effector, a fifth substrate on the third end effector; and placing, by a fourth end effector, a sixth substrate onto the third substrate support, wherein the fourth end effector is attached to the robot apparatus.

Further disclosed herein are methods of transporting substrates by a robot apparatus, comprising: retrieving from a first substrate support within a first process chamber, by a first end effector, a first substrate on the first end effector, wherein the first end effector is attached to the robot apparatus; placing, by a second end effector, a second substrate onto the first substrate support, wherein the second end effector is attached to the robot apparatus; retrieving from a second substrate support in a second process chamber, by the second end effector, a third substrate on the second end effector; placing, by a third end effector, a fourth substrate onto the second substrate support, wherein the third end effector is attached to the robot apparatus; retrieving from a third substrate support in a third process chamber, by the third end effector, a fifth substrate on the third end effector; and placing, by a fourth end effector, a sixth substrate onto the third substrate support, wherein the fourth end effector is attached to the robot apparatus.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

FIG. 1A illustrates an above view of a substrate processing system including a robot apparatus according to one or more embodiments.

FIG. 1B illustrates an above view of a substrate processing system including a robot apparatus according to one or more embodiments.

FIG. 2A illustrates a perspective view of a robot apparatus including four independently-controllable forearms each with an end effector according to one or more embodiments.

FIG. 2B illustrates a side plan view of a robot apparatus including four independently-controllable forearms each with an end effector according to one or more embodiments.

FIG. 3A illustrates a perspective view of a robot apparatus including two independently rotatable forearms each forearm including two wrists each with an end effector according to one or more embodiments.

FIG. 3B illustrates a side plan view of a robot apparatus including two independently-controllable forearms each forearm including two wrists each with an end effector according to one or more embodiments.

FIG. 4 illustrates a perspective view of a robot apparatus with a forearm including a pair of twin wrists including an end effector on each wrist according to one or more embodiments.

FIG. 5 illustrates a perspective view of a robot apparatus with a forearm including three twin wrists including an end effector on each wrist according to one or more embodiments.

FIG. 6 illustrates a perspective view of a robot apparatus with four in-line extendable wrists each with an end effector according to one or more embodiments.

FIG. 7A is a flowchart illustrating a method of transporting substrates to and from processing chambers, according to one or more embodiments.

FIG. 7B is a flowchart illustrating a method of transporting substrates to and from processing chambers, according to one or more embodiments.

FIG. 8 is a flowchart illustrating a method of transporting substrates to and from processing chambers, according to one or more embodiments.

### DETAILED DESCRIPTION

Precision and efficiency in transporting substrates between various locations in electronic device transport systems is sought. However, in some systems, transfer between the various chambers may become a bottleneck that limits efficiency. In steady state production it is ideal to keep the processes running 100% of the time for maximum utilization. To optimize efficiency, a robot should be configured to hold as many substrates as a process chamber can process per cycle. Maintaining at least one empty end effector enables the unload and reload of a process chamber (or in some instances a set of process chambers) in one cycle, so the robot does not have to return to a load lock or another station to unload and reload. In a system that is process limited, for example, has an hour long process, the most efficient sequence is to open the slit valve, unload and reload all substrates, and then close the slit valve, minimizing the overhead in the substrate transfer process to maximize productivity. Being able to quickly open the slit valve and close the slit valve when the system is process limited, maximizes utilization of the process chambers—getting 10 more processed substrates per hour can significantly improve return on investment.

In traditional electronic device manufacturing systems, the robots do not reload the chamber directly (i.e., in one load/unload cycle). Instead, the robot performs multiple cycles to unload a full process chamber of processed substrates, and performs multiple cycles to reload the process chamber with unprocessed substrates. For example, a standard setup is a two arm robot, which includes two end effectors, each of which can hold a substrate. To empty and refill a quad chamber, the robot retrieves two processed substrates from the process chamber, moves to the load lock, places the two processed substrates at the load lock, picks up two unprocessed substrates from the load lock (or another load lock), returns to the process chamber, places the two unprocessed substrates at the process chamber, retrieves the remaining two processed substrates from the process chamber, returns to the load lock, places the two processed substrates at the load lock, picks up two more unprocessed substrates, returns to the process chamber, and places the two more unprocessed substrates in the process chamber. Similarly, a robot having two end effectors can remove and replace (i.e., swap) one substrate at a time for a quad pedestal (i.e., four substrate supports) process chamber, but still requires four visits between the process chamber and the load lock. In contrast, embodiments described herein provide an electronic device manufacturing system in which the transfer chamber robot has a capacity that is at least one greater than a process chamber capacity (or combined process chamber capacity of a set of process chambers). Embodiments, enable a load/unload sequence to be performed in a single cycle, drastically increasing the throughput of the transfer chamber robot.

Embodiments described herein relate to systems including at least one process chamber, at least one load lock and a robot apparatus (also referred to herein as a robot assembly or simply a robot) to maximize substrate handling efficiency when transporting substrates between the at least one process chamber and the at least one load lock (or via or pass-through). The at least one process chamber can be a multi-substrate process chamber having a plurality of substrate supports within the chamber and, if present, one or more additional substrate supports within a substrate holding chamber (a.k.a. a “via”). In embodiments, the at least one multi-substrate process chamber includes N substrate supports within a single chamber or N substrate supports both within the chamber and in a substrate holding chamber, where N is an integer greater than or equal to 2. For example, the chamber may include three (3) substrate supports and the substrate holding chamber may also include three (3) substrate supports (N=6). Each substrate support is configured to hold one substrate. Alternatively, a group of process chambers and/or vias may together include N substrate supports. For example, a transfer chamber may be connected to six process chambers each of which can accommodate a single substrate at a time, in which case the six process chambers together may have six substrate supports (e.g., where N=6).

The substrates can be of any suitable material for processing. The substrates can include, but are not limited to silicon wafers, masks, glass, displays, etc. In embodiments, N may include four substrate supports (i.e., N=4), five substrate supports (i.e., N=5), six substrate supports (i.e., N=6), seven substrate supports (i.e., N=7), eight substrate supports (i.e., N=8), nine substrate supports (i.e., N=9) and so on.

In embodiments, the system includes a plurality of single substrate process chambers, that is, each chamber has one substrate support. The total number of substrate supports within all of the process chambers in the system is N, where N is an integer greater than or equal to 2. For example, a system may include three (3) single substrate process chambers (N=3) and no substrate supports within a substrate holding chamber.

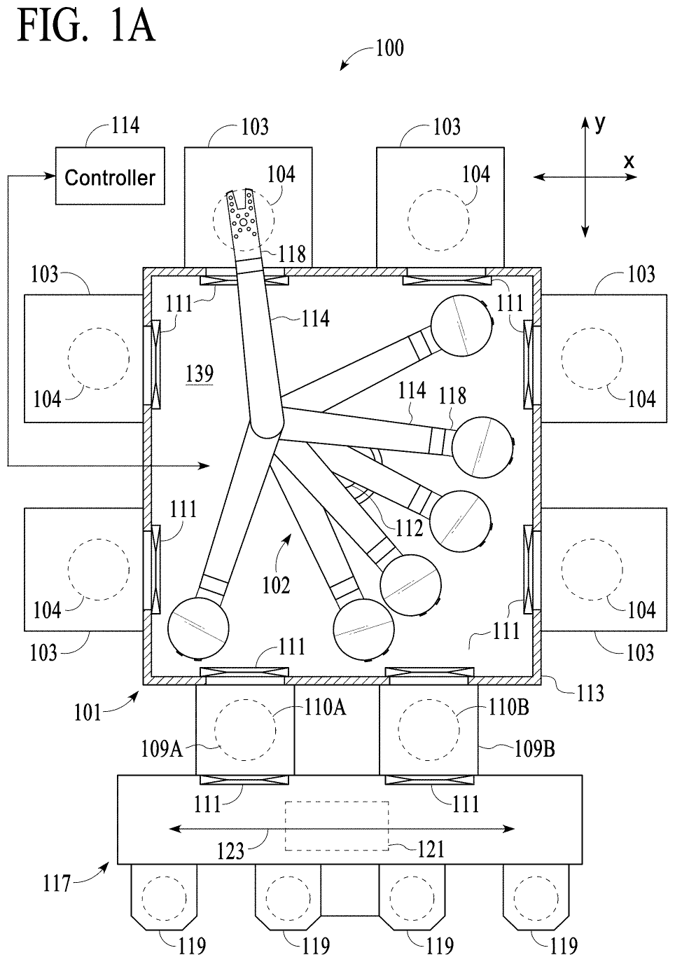

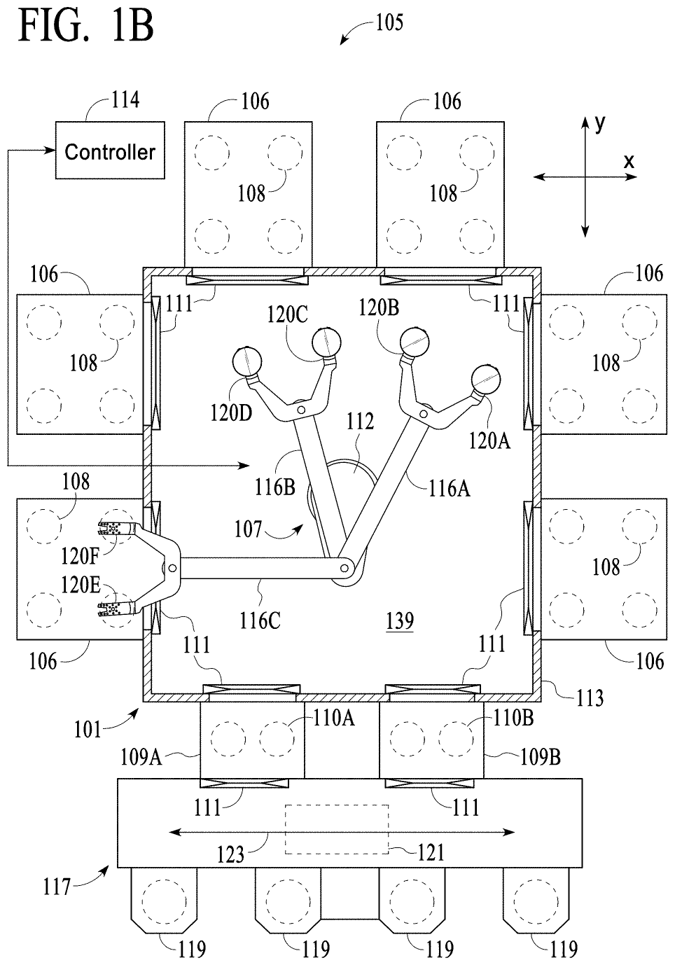

The at least one process chamber can be any suitable shape. For example, the at least one process chamber can be square, linear (e.g., rectangular), radial, a hybrid combination of any of the foregoing or any other shape known to those of ordinary skill in the art. In embodiments, the at least one process chamber is any suitable shape supported by the robot apparatus kinematics, for example, a radial SCARA with at least N+1 or at least N+2 end effectors on a radial mainframe (i.e., transfer chamber) or a mainframe with another shape. As shown, for example, in FIGS. 1A and 1B, the transfer chamber may have a square shape with four equally sized sides (also referred to as facets). Alternatively, the transfer chamber may have a rectangular shape with two approximately parallel facets having a first length and two approximately parallel facets having a second length. The mainframe/transfer chamber may also have other numbers of sides/facets, such as 5 sides, 6 sides, seven sides, eight sides, and so on. The sides may have the same dimensions as one another, or may have different dimensions.

The robot apparatus is configured to unload and reload (e.g., swap, retrieve and place) substrates within the at least one process chamber in a single load/unload cycle (i.e., without returning to a load lock or another station to retrieve and/or place substrates before completely swapping the substrates in the at least one process chamber). To accomplish this single cycle swap, the robot apparatus includes at least N end effectors plus one end effector (N+1). In embodiments, the robot apparatus includes at least N plus two end effectors (N+2), or at least N+3, or at least N+4 and so on. Of the at least N+1 end effectors, N of the end effectors can hold N substrates, leaving at least one end effector empty. Such use of robots with at least N+1 end effectors can, for example, reduce the number of cycles that are used to fill a process chamber with substrates and/or reduce the number of cycles that are used to complete removal and replacement of processed wafers in a process chamber with unprocessed substrates. Robots having at least N+1 end effectors as described herein can significantly improve the throughput and efficiency of an electronic device processing system in some use cases, such as cases in which transfer time (the time that it takes to transfer substrates into and/or out of a process chamber) is greater than or on the order of process time (the time used to actually perform a process on wafers in a process chamber).

For example, if a multi-substrate process chamber includes three (3) substrate supports, the robot apparatus in embodiments includes at least four (4) end effectors. During a transfer, three of the end effectors hold unprocessed substrates while the fourth end effector is empty. The robot apparatus is positioned to access the substrate supports within the multi-substrate process chamber. Using the empty end effector, the robot apparatus retrieves a first processed substrate from a first substrate support. The robot then places an unprocessed second substrate on the first substrate support using a second end effector holding the unprocessed substrate. The second end effector is then empty, and can retrieve a second processed substrate from the process chamber. A third end effector can then place a second unprocessed substrate in the process chamber, rendering that third end effector empty. The now empty third end effector can then retrieve a third processed substrate from the process chamber. The fourth end effector can then place a third unprocessed substrate in the process chamber. The robot can then move to the load lock, and can place the three processed substrates in the load lock chamber. Thus, the robot is capable of swapping out three unprocessed substrates for three processed substrates in a single cycle (i.e., visit to the process chamber).

In embodiments, a system may include at least one multi-substrate process chamber containing multiple substrate supports that are accessible by a robot apparatus having a forearm or wrist member with “twin” end effectors. The multiple substrates may be positioned radially within the process chamber or in rows in embodiments. The twin end effectors are configured to simultaneously retrieve two substrates from two substrate supports at a time. In embodiments, the multi-substrate process chamber can include four substrate supports (N=4) in two rows (e.g., two rows in from the opening of the chamber) and the robot apparatus can include three forearms, each with twin end effectors at a distal end thereof (resulting in N+2 end effectors). During a substrate transfer, four (4) of the end effectors can hold four (4) unprocessed substrates and two of the end effectors are empty. The empty twin end effectors can simultaneously retrieve two processed substrates from two of the substrate supports. The robot apparatus then rotates and simultaneously places two unprocessed substrates on the two empty substrate supports. The now empty end effectors then retrieve the remaining two processed substrates from the other substrate supports. The robot apparatus then places the remaining two unprocessed substrates onto the empty substrate supports. The complete swap of the processed substrates with the unprocessed substrates is completed within a single cycle.

Systems as described herein can include a robot apparatus having three or more end effectors. End effector (also referred to as blades) as used herein means a portion of or attachment to a forearm or wrist member that is configured to hold a substrate. Robot apparatus embodiments described herein can include one or more arm component and at least N+1 end effectors coupled to the one or more arm component.

Systems as described herein further include at least one load lock containing at least one substrate support. The at least one load lock can be a single substrate load lock or a multi-substrate load lock. In embodiments, the system can include at least two load locks. One load lock can be designated for loading and the other load lock can be designated for unloading. In embodiments, both load locks can be configured for loading and unloading. The productivity of the system can be increased through the use of at least one multi-substrate load lock where the robot apparatus having at least N+1 end effectors is configured to simultaneously swap all N substrates between the end effectors and the substrate supports within the multi-substrate load lock. For example, the load lock can include N substrate supports and if the substrate supports are all empty, the robot apparatus can be configured to simultaneously place all N substrates on the substrate supports. In embodiments, the robot apparatus is then positioned by an adjacent multi-substrate load lock to simultaneously retrieve N unprocessed substrates from N substrate supports in the adjacent load lock.

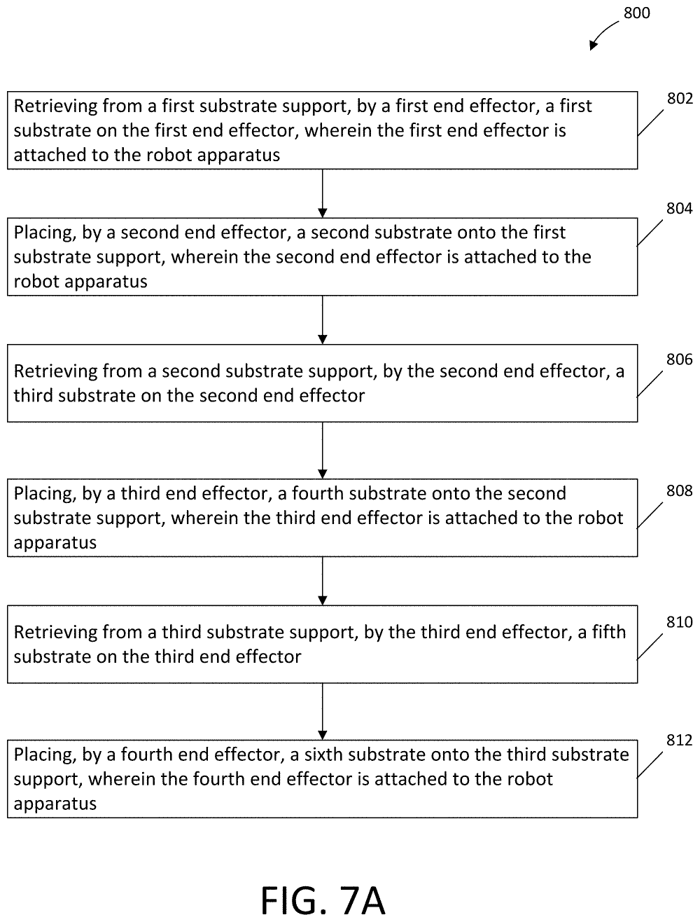

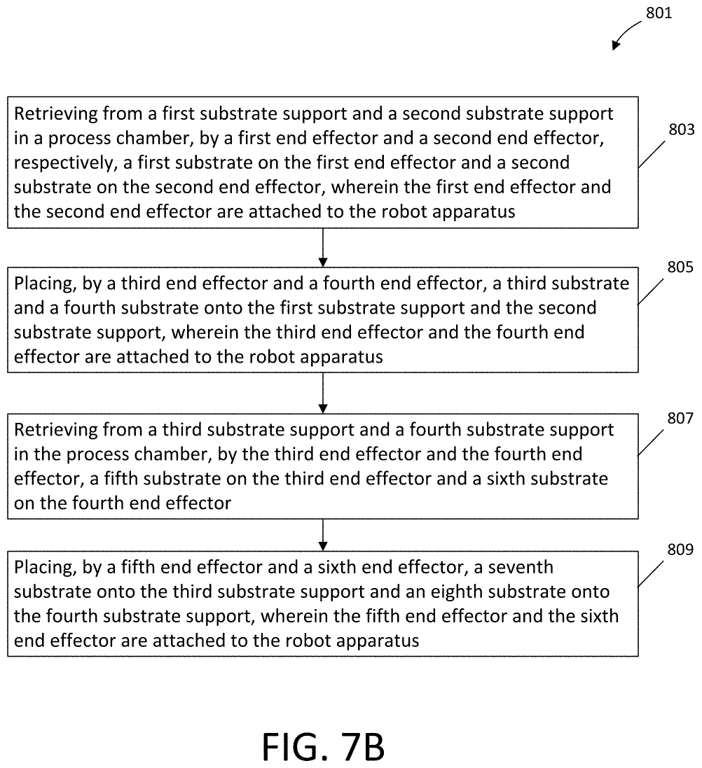

Further details and example embodiments illustrating various aspects of the systems and robot apparatus are described with reference to FIGS. 1A-8 herein.

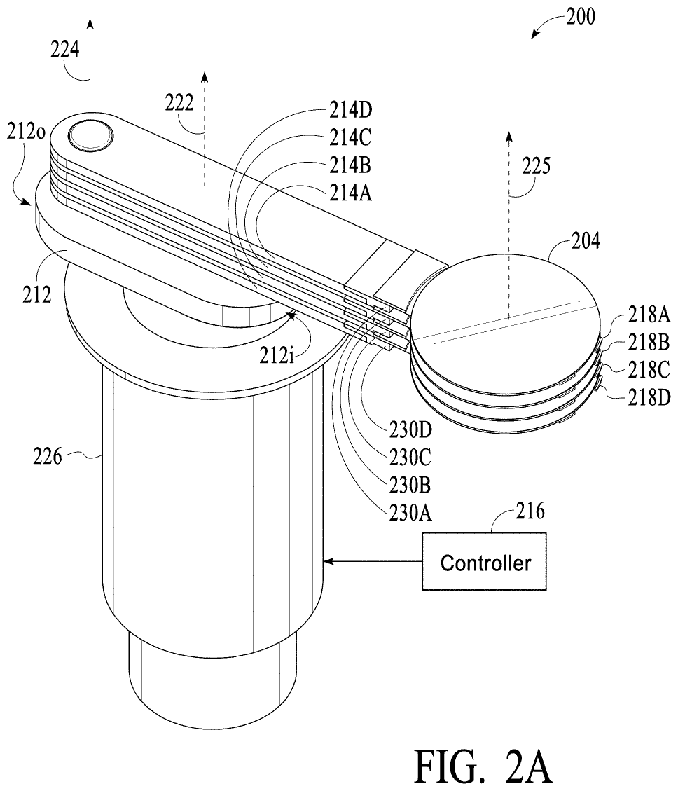

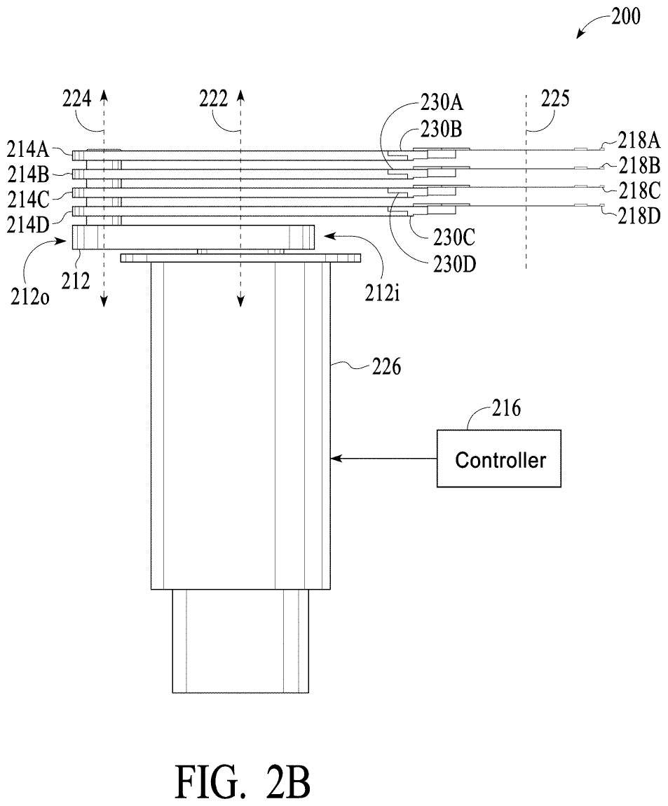

Referring now to FIG. 1A, an example embodiment of an electronic device manufacturing system 100 according to embodiments of the present disclosure is provided. The electronic device processing system 100 can include a mainframe 101 including a transfer chamber 113 and at least two process chambers 103. A housing of the mainframe 101 includes the transfer chamber 113 therein. The transfer chamber 113 can include a top wall (not shown), bottom wall (floor) 139, and side walls. In some embodiments, the transfer chamber 113 may be maintained in a vacuum. In the depicted embodiment, a robot apparatus 102, such as depicted in FIGS. 2A-B, 3A-B, 4, 5 and 6, is mounted to the bottom wall (floor) 139. However, it could be mounted elsewhere, such as to the top wall (not shown—removed for clarity). As discussed above, the transfer chamber can be any suitable shape known to those of ordinary skill in the art.

Process chambers 103 may be adapted to carry out any number of processes on the substrates (not shown). The processes can include deposition, oxidation, nitration, etching, polishing, cleaning, lithography, metrology, or the like. Other processes may be carried out, as well. Each process chamber 103 may include at least one substrate support 104. The total number of substrate supports N shown in system 100 of FIG. 1A is six (6).

The robot apparatus 102 may include at least N+1 end effectors to transport substrates. In the illustrated embodiment, the robot apparatus 102 includes an arm 112. The arm 112 includes seven forearms 114A-114G, each having a corresponding end effector 118A-118G attached thereto. As shown, each single blade 118A may transport one substrate at a time.

System 100 further includes a load lock apparatus 109A, 109B configured to interface with a factory interface 117 or other system component, that may receive substrates from substrate carriers 119 (e.g., Front Opening Unified Pods (FOUPs)) that can be docked at load ports of the factory interface 117, for example. A load/unload robot 121 (shown dotted) may be used to transfer substrates between the substrate carriers 119 and the load lock apparatus 109A, 109B. Transfers of substrates may be carried out in any sequence or direction. Load/unload robot 121 may be similar to the robot apparatus 102 in some embodiments, but may include a mechanism to allow the robot apparatus to move laterally in either lateral direction as indicated by arrow 123. In one embodiment, robot apparatus 102 is configured to operate in vacuum, while load/unload robot 121 may not be configured to operate in vacuum. Any other suitable robot can be used. As shown, transfers may occur through slit valves 111 and the substrates may be retrieved, and or deposited, from or to load lock apparatus 109A and 109B.

Each load lock 109A, 109B includes at least one substrate support 110A, 110B. In embodiments, load lock 109A can be configured for robot 102 to retrieve unprocessed substrates (i.e., the inlet) as loaded from substrate carriers 119 and load lock 109B can be configured to place processed substrates as received from the process chambers 103 (i.e., the outlet). In embodiments, each load lock 109A, 109B contains N substrate supports. The N substrate supports can be pitched to enable at least some of the N processed substrates held by end effectors 118A-118G of robot 102 to be simultaneously retrieved from or placed by robot 102 on substrate supports 110 in load lock 109A, 109B. In embodiments, each load lock 109A, 109B may contain N+1 substrate supports, even if not all substrate supports are used during a cycle. In embodiments, one or more load locks 109A, 109B may contain fewer than N substrate supports (e.g., may contain a single substrate support).

In the use case shown in FIG. 1A, the seven (7) blade robot 102 sequentially unloads and reloads substrates from and to each process chamber 103. For example, the robot carrying six (6) unprocessed substrates (N=6) on end effectors 118A-118F, has one (+1) empty end effector 118G (for example). The empty end effector 118G retrieves a processed substrate from a substrate support 104 in a first one of the process chambers 103. The robot 102 then places an unprocessed substrate using end effector 118A (for example) on the empty substrate support in the first process chamber 103. The robot 102 then moves to a second one of the process chambers 103, for example, robot 102 may move to an adjacent process chamber 103 or may move to the next closest process chamber 103 that has completed processing. In embodiments, the robot 102 follows a first in-first out sequence in moving between process chambers. At the next process chamber 103, using the empty end effector 118A, the robot retrieves a processed substrate from the process chamber 103 and using end effector 118B (for example) places an unprocessed substrate on the empty substrate support. Once the robot 102 has swapped processed substrates with unprocessed substrates in all of the process chambers 103 within the system 100, the robot 102 then returns to the load locks 109A, 109B to exchange the processed substrates with unprocessed substrates. Using an empty end effector 118F (for example), the robot 102 retrieves an unprocessed substrate from a substrate support within the load lock 109A and places a processed substrate on the empty substrate support. The robot 102 continues to swap unprocessed substrates with processed substrates until six (N) end effectors 118B-118G (for example) hold unprocessed substrates and one end effector 118A (for example) is empty. The robot 102 may then proceed to sequentially unload/reload the process chambers 103.

In embodiments where the load lock 109A, 109B contains a plurality of substrate supports (e.g., N substrate supports), the pitch of load lock slots and the robot blades 118B-118G (for example) may enable the robot 102 to unload a plurality of processed substrates (e.g., N) simultaneously and to reload a plurality of unprocessed substrates (e.g., N) simultaneously. In embodiments, load lock 109A can be configured for unloading and load lock 109B can be configured for loading. In other embodiments, system 100 may have only one load lock 109 (not shown). The single load lock may be a single substrate load lock, or may include more than one substrate supports (e.g., N substrate supports). In one embodiment, the load lock contains N×2 substrate supports, for example, two rows of N substrate supports. The robot 102 may simultaneously place a plurality of substrates (e.g., N) on the row of empty substrate supports and may simultaneously retrieve a plurality of substrates (e.g., N) from the row holding unprocessed substrates in an embodiment.

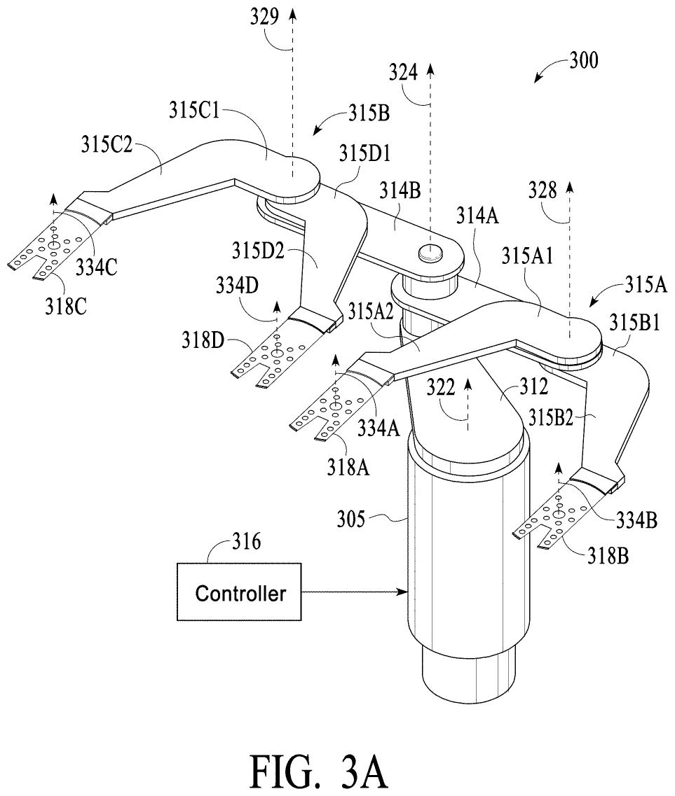

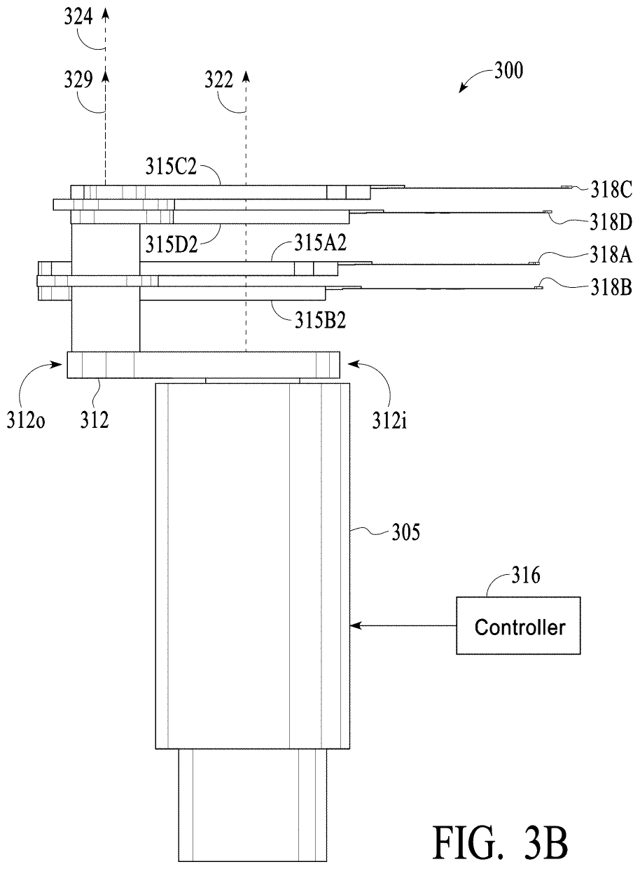

Referring now to FIG. 1B, an example embodiment of an electronic device manufacturing system 105 according to embodiments of the present disclosure is provided. The electronic device processing system 105 can include a mainframe 101 including the transfer chamber 113 and at least two process chambers 106. A housing of the mainframe 101 includes the transfer chamber 113 therein. The transfer chamber 113 can include top wall (not shown), bottom wall (floor) 139, and side walls. In some embodiments, the transfer chamber 113 may be maintained in a vacuum. In the depicted embodiment, a robot apparatus 107, such as depicted in FIGS. 2A-2B, 3A-B, 4, 5 and 6, is mounted to the bottom wall (floor) 139. However, it could be mounted elsewhere, such as to the top wall (not shown—removed for clarity). As discussed above, the transfer chamber can be any suitable shape known to those of ordinary skill in the art.

Process chambers 106 may be adapted to carry out any number of processes on the substrates (not shown). The processes can include deposition, oxidation, nitration, etching, polishing, cleaning, lithography, metrology, or the like. Other processes may be carried out, as well. Each process chamber 106 may include N substrate supports 108 where N=4 in FIG. 1B. Alternatively, each process chamber may include N/2 substrate supports. For example, Two process chambers together may have a combined N number of substrate supports (e.g., two dual process chambers may together have N=4).

The robot apparatus 107 may include at least N+2 end effectors to transport substrates. In the illustrated embodiment, the robot apparatus 107 includes an arm 112. The arm 112 includes three twin forearms 116A-116C, each having a pair of end effectors 120A-120F. As shown, a single forearm 116A, may include two forearm limbs each having an end effector 120A-120B attached at the end of the limb to transport two substrates at a time. System 105 further includes a load lock apparatus 109A, 109B, factory interface 117, substrate carriers 119, and load/unload robot 121, as described with reference to FIG. 1A.

In the use case shown in FIG. 1B, the triple twin blade robot 107 may sequentially unload and reload substrates from and to each process chamber 106. For example, the robot 107 carrying four (4) unprocessed substrates (N=4) on end effectors, has two (+2) empty end effectors 120E, 120F (for example). The empty end effectors 120E, 120F retrieve two processed substrates from two substrate supports 108 in a first one of the process chambers 106. The robot 107 then rotates the blades and places two unprocessed substrates using end effectors 120A, 120B (for example) on the empty substrate supports in the first process chamber 106. Using the empty end effectors 120A, 120B, the robot 107 then retrieves the remaining two processed substrates from the remaining two substrate supports 122 and places two unprocessed substrates using end effectors 120C, 120D on the empty substrate supports 122. The robot 107 then returns to the load lock 109A to exchange the processed substrates with unprocessed substrates two at a time. Using the empty end effectors 120C, 120D (for example), the robot 107 may retrieve two unprocessed substrates from two substrate supports within the load lock 109A and place two processed substrates on the empty substrate supports. The robot 107 may continue to swap unprocessed substrates with processed substrates two at a time until four (N) end effectors 120C-120F (for example) hold unprocessed substrates and two end effectors 120A, 120B (for example) are empty. The robot 107 may then proceed to unload/reload the process chambers 106.

In alternative embodiments, the robot 107 can be configured as described with respect to FIG. 1A, such that the robot includes five (5) blades. In this embodiment, the robot may carry four (N=4) unprocessed substrates on four end effectors with the fifth end effector (+1) empty. The robot sequentially unloads and reloads substrates one at a time from a process chamber 106 using the empty end effector to retrieve a processed substrate and placing an unprocessed substrate on the empty substrate support using the other end effectors, until the substrates processed for unprocessed have been completely swapped.

FIG. 2A illustrates a perspective view of a robot apparatus 200 including four independently-controllable forearms 214A-214D each with a corresponding end effector 218A-218D. FIG. 2B illustrates a side plan view of the robot apparatus 200 having four independently-controllable forearms 214A-214D each with a corresponding end effector 218A-218D according to one or more embodiments.

In an embodiment, robot apparatus 200 corresponds to robot apparatus 102 of FIG. 1A or robot apparatus 107 of FIG. 1B. In such embodiments, the robot apparatus 200 may be configured and adapted to transfer substrates between various process chambers 103, 106 and/or to exchange substrates at one or more load lock apparatus 109A, 109B, for example. In the depicted embodiment of FIG. 1A, two load lock apparatus 109A, 109B are shown. However, the robot apparatus 200 could be used with only one load lock apparatus or more than two load lock apparatus.

The robot apparatus 200 has an arm 212 including an inboard end 212i and outboard end 212o. The inboard end 212i is configured to be rotatable about a shoulder axis 222 by an arm drive motor of a drive motor assembly 226. A drive assembly of driving and driven pulleys and transmission members is included within arm 212.

The robot apparatus 200 shown includes four forearms 214A-214D coupled to the outboard end 212o of the arm 212 opposite from the inboard end 212i. Each forearm 214A-214D has a corresponding blade 218A-218D. Each forearm 214A-214D is independently rotatable about the outboard axis 224 through the commanded action of a first drive motor, and a second drive motor, respectively. The first drive motor and second drive motor are commanded by a suitable control signal received from a controller 216. Controller 216 can be any suitable processor, memory, electronics and/or drivers capable of processing control instructions and carrying out motion of forearm 214A-214D.

Arm 212 can have a center-to-center length of L1, wherein the centers of the length L1 are the shoulder axis 222 and the outboard axis 224. Each of the blades 218A-218D in the depicted embodiment can be made up of a forearm member, namely first forearm 214A, a second forearm 214B, a third forearm 214C and a fourth forearm 241C. Further, each of the forearms 214A-214D in the depicted embodiment includes an end effector 218A-218D, namely first end effector 218A, a second end effector 218B, third end effector 218C and fourth end effector 218D that are each configured and adapted to support and transport a substrate thereon.

The forearms 214A-214D each have a center-to-center length L2 wherein the centers of the length L2 for the forearms 214A-214D are the outboard axis 224 and a nominal center 225 of an end effector location corresponding to end effectors 218A-218D. The nominal center 225 is where the substrate will rest on each of the first, second, third, and fourth end effectors 218A-218D when nominally positioned thereon, as depicted. Restraining features restrain location of the substrates on the end effectors 218A-218D within limits. In the depicted embodiment, the forearms 214A-214D, and the end effectors 218A-218D are separate interconnected members. However, it should be understood that each forearm member and end effector may be integrally formed in some embodiments and constitute one unitary component. In the depicted embodiment, each of the forearm members 214A-214D may include a corresponding orientation adjuster 230A-230D at the end thereof to allow for fine orientation adjustments (e.g., adjustments for droop and/or tilt) to each of the end effectors 218A-218D. The orientation adjusters 230A-230D can use screws and/or shims to accomplish end effector attitude adjustments.

Thus, it should be apparent that the first forearm 214A is configured for independent rotation relative to arm 212 about the outboard axis 224, and wherein the first forearm 214A includes the first end effector 218A. The first forearm member 214A may be positioned directly above the second forearm member 214B with the first end effector 218A correspondingly above the second end effector 218B. Likewise, the second forearm 214B may be configured for independent rotation relative to the arm 212 about the outboard axis 224. The second forearm member 214B may be positioned directly above the third forearm member 214C with the second end effector 218B correspondingly above the third end effector 218C. Likewise, the third forearm 214C may be configured for independent rotation relative to the arm 212 about the outboard axis 224. The third forearm member 214C may be positioned directly above the fourth forearm member 214D with the third end effector 218C correspondingly above the fourth end effector 218D. Likewise, the fourth forearm 214D may be configured for independent rotation relative to the arm 212 about the outboard axis 224. The rotation is provided by the drive motor assembly 226 and the drive assembly described below.

As can be seen in FIGS. 2A-2B, the first end effector 218A, second end effector 218B, third end effector 218C, and fourth end effector 218D lie one above another when configured in a folded and zeroed configuration (e.g., in a vertically stacked configuration), as shown. This folded and zeroed configuration is the neutral configuration and the forearms 214A-214D, can be rotated approximately +/−170 degrees from this orientation, for example, using a traditional SST band drive linkage. In embodiments, if the motor is located at the axis, for example, there can be unlimited range of motion.

FIG. 3A illustrates a perspective view of a robot apparatus 300 according to disclosed embodiments. FIG. 3B illustrates a plan view of robot apparatus 300 according to disclosed embodiments. Robot apparatus 300 includes an arm 312 that rotates about a first rotational axis 322. A first forearm 314A may be attached to a distal end of the arm 312 such that it rotates about a second rotational axis 324. Two wrist members 315A, 315B may be attached to a distal end of the forearm 314A such that they each rotate about a third rotational axis 328. A first wrist member 315A may be positioned above the forearm 314A, and a second wrist member 315B may be positioned beneath the forearm 314A. The first wrist member 315A and the second wrist member 315B may be L-shaped. The first wrist member 315A may include a first leg 315A1 and a second leg 315A2. The first leg 315A1 may be rotatably coupled to the forearm 314A about the third rotational axis 328 at a rotation point. The second leg 315A2 may be longer than the first leg 315A1 and may be coupled to a first end effector 318A.

The second wrist member 315B may include a first leg 315B1 and a second leg 315B2. The first leg 315B1 may be rotatably coupled to the forearm 314A about a fourth rotational axis 329 at the rotation point. The second leg 315B2 may be longer than the first leg 315B1 and may be coupled to a second end effector 318B.

A second forearm 314B may be attached to a distal end of the arm 312 such that it rotates about the second rotational axis 324. Two wrist members 315C, 315D may be attached to a distal end of the forearm 314B such that they each rotate about the third and fourth rotational axes 328, 329. A third wrist member 315C may be positioned above the forearm 314B, and a fourth wrist member 315D may be positioned beneath the forearm 314B. The third wrist member 315C and the fourth wrist member 315D may be L-shaped. The third wrist member 315C may include a first leg 315C1 and a second leg 315C2. The first leg 315C1 may be rotatably coupled to the forearm 314B about the fourth rotational axis 329 at a rotation point. The second leg 315B2 may be longer than the first leg 315B1 and may be coupled to a third end effector 318C.

The fourth wrist member 315D may include a first leg 315D1 and a second leg 315D2. The first leg 315D1 may be rotatably coupled to the forearm 314B about the fourth rotational axis 329 at the rotation point. The second leg 315D2 may be longer than the first leg 315D1 and may be coupled to a fourth end effector 318D.

The first legs 315A1, 315B1, 315C1, 315D1 may include a bend that provides for the vertical alignment of the first and third end effectors 318A and 318C and the second and fourth end effectors 318B and 318D. Thus the second and fourth end effectors 318B, 318D may be positioned beneath the first and third end effectors 318A, 318C.

The embodiment of the robot apparatus 300 shown in FIGS. 3A and 3B may be adapted for use in the substrate processing system 100 of FIG. 1A and system 105 of FIG. 1B. In operation, the arm 312 may be rotated so as to position the end effectors 318A-318D adjacent a target destination (e.g., a process chamber 103, 106 or a load lock chamber 109A-B) to pick or place a substrate. The arm 312 and one of the forearms 314A, 314B then may be suitably actuated (e.g., rotated) to extend a wrist member 315A-315D to or from the target destination. As the wrist member 315A-315B moves from the first rotational axis 322, the wrist member 315A-315D may rotate in opposite directions about the third and fourth rotational axes 328, 329. The center of the nominal substrate placement locations 334A, 334B on the end effectors 318A-318D may be separated by a first distance, which may be dependent on a second distance between end effectors 318A-D and the first rotational axis 322.

The first forearm 314A including the first and second end effector 318A, 318B and the second forearm 314B including the third and fourth end effectors 318C, 318D may be inserted into a process chamber (e.g., 103, 106) simultaneously through a multi-slit valve (e.g., a dual slit valve) in a straight line manner, i.e., inserted in a direction substantially perpendicular to a facet or side of a process chamber 103, 106. While passing through the dual slit valves, the first and second end effectors 318A, 318B and the third and fourth end effectors 318C, 318D may be at a first pitch that provides for the first separation distance between nominal substrate placement centers of the first and third end effectors 318A, 318C (and second and fourth end effectors 318B and 318D). This first separation distance may match an opening offset distance of the dual slit valves. Note that each slit valve of the dual slit valve may be a double height slit valve that is sized to accept two vertically stacked end effectors (e.g., end effectors 318A, 318B).

Once through the dual slit valves, the first and third end effectors 318A, 318C (and second and fourth end effectors 318B, 318D) may be rotated apart about the third rotational axis 328 or fourth rotational axis to a second pitch that provides for a second separation distance between the nominal substrate placement centers of the first and third end effectors 318A, 318C (and second and fourth end effectors 318B and 318D). For example, the first wrist member 315A and the second wrist member 315B may rotate about the third rotational axis 328. The second separation distance may match a processing distance between dual processing locations within a process chamber 103, 106 which is wider than the distance between the dual slit valves.

Similarly, the end effectors 318A-318D may be inserted simultaneously into the load lock chamber 109A-B (FIGS. 1A-1B) through the slit valves (which may be double height dual slit valves) in a straight line manner. While passing through the slit valves, the end effectors 318A-318D may be at the first pitch. For example, the distance between end effectors 318A and 318B may have a first value. Once through the slit valves, the first and second end effectors 318A, 318B may remain at the first pitch or be rotated outward to the second pitch. For example, the first wrist member 315A and the second wrist member 315B may rotate about the third rotational axis 328 to a second value for the distance between end effectors 318A and 318B. The second value of the distance may be selected to be approximately a same separation distance between centers of dual transfer locations within the load lock chamber 109A-B. The processes described above may be applied in reverse order as the first end effector 318A and the second end effector 318B are retracted from a process chamber 103, 106 or the load lock chamber 109A-B.

This variable pitch robot apparatus 300 can also be used to access two twin slit valve sets that are not at the same pitch. In some embodiments, two adjacent load lock chambers are horizontally spaced by a first pitch D1. In some embodiments, the first pitch D1 between centers of the two adjacent load lock chambers may be in a range of about 20 inches to about 25 inches. Other distances for the first pitch D1 may also be possible.

According to embodiments, at least one pair of two adjacent process chambers are horizontally spaced by a second pitch D2 that is different from the first pitch D1 (e.g., second pitch D2 may be greater than first pitch D1). In some embodiments, the second pitch D2 between centers of the two adjacent process chambers 120 may be in a range of about 32 inches to about 40 inches. Other distances for the second pitch D2 may also be possible.

One or more of the load lock chambers may be accessed by the robot apparatus 300 through slit valves. One or more of the process chambers also may be accessed by the robot apparatus 300 through slit valves.

The slit valves may have a slit valve width that allows the robot apparatus 300, and particularly, a first end effector 318A and a second end effector 318B, to access them in either a dual substrate handling mode or a single substrate handling mode. In certain embodiments, the first end effector 318A and/or the second end effector 318B access the slit valve(s) orthogonally (relative to the horizontal opening of slit valve). In alternative embodiments, the first end effector 318A and/or the second end effector 318B access the slit valve(s) at an angle (relative to the horizontal center line of slit valve). The first and/or the second end effector(s) 318A, 318B may access one or more of the slit valve(s) at an angle ranging from about 0° to about 20°, from about 5° C. to about 17°, or from about 7° to about 14° relative, when measured relative to the horizontal center line of slit valve.

The substrate processing system may be described by the first wrist member 315A and the second wrist member 315B configured to rotate the first end effector 318A to a first pitch providing for a first end effector distance between the first end effector 318A and the second end effector 318B while at an initial distance from the first rotational axis 328. The first wrist member 315A and the second wrist member 315B may rotate in opposite directions to a second pitch providing for a second end effector distance between the first end effector 318A and the second end effector 318B while at an extended distance from the first rotational axis 328. Accordingly, the distance between end effectors 318A and 318B may be dependent on a distance the wrist members are extended and kinematically determined by cams in the robot apparatus 300 that are part of a pulley system that drives wrist members 315A, 315B.

In some embodiments, the robot apparatus 300 may include additional forearm members, wrist members and end effectors to provide the ability to transport additional substrates. For example, the robot apparatus may include a third forearm rotatable relative to the arm 312 about the forearm axis 324. A fifth and sixth wrist member may be rotatable relative the third forearm member about a wrist axis. A fifth end effector may be attached to the distal end of the fifth wrist member and a sixth end effector may be attached to the distal end of the sixth wrist member. The fifth end effector may be below the third end effector and may have a fixed position relative to the third end effector. Similarly, the sixth end effector may be below the fourth end effector and may have a fixed position relative to the fourth end effector. The fifth and sixth wrist members may be dependently rotatable about the wrist axis. When in a retracted position, the fifth wrist member may be positioned directly under the first and third wrist members and the sixth wrist member may be positioned directly under the second and fourth wrist members. The fifth and sixth wrist members may be configured to provide a first distance between the distal ends of the fifth and sixth wrist members when retracted and the same distance, or a second distance, between the distal ends when extended.

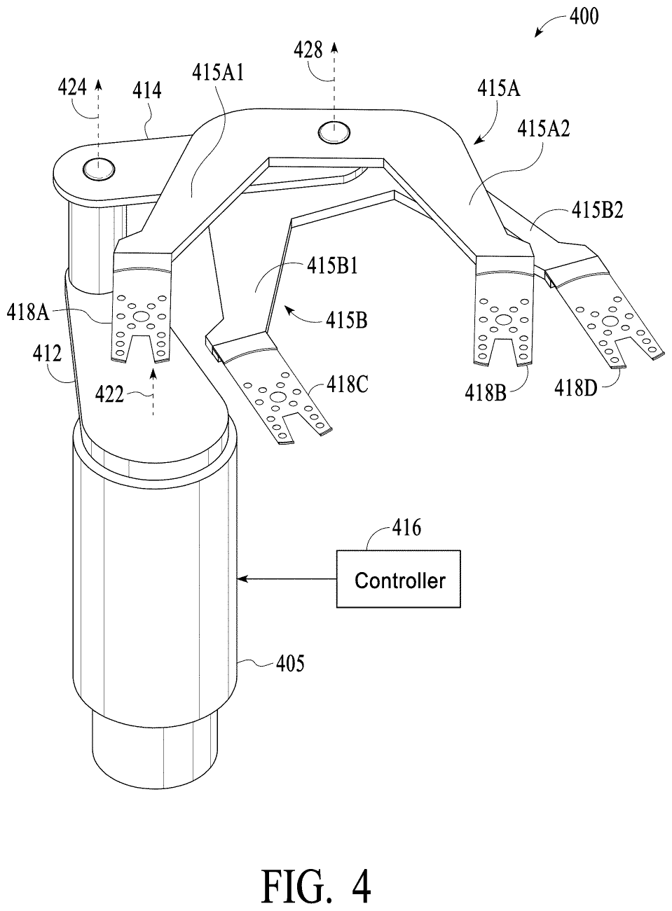

FIG. 4 depicts another example of a robot apparatus 400 with two twin forearm members. Robot apparatus 400 includes an arm 412 that rotates about a first rotational axis 422. A forearm 414 may be attached to a distal end of the arm 412 such that it rotates about a second rotational axis 424. Two twin wrist members 415A and 415B may be attached to a distal end of the forearm 414 such that they each rotate about a third rotational axis 428. The first twin wrist member 415A may be positioned above the second twin wrist member 415B and the twin wrist members 415A, 415B may be U-shaped. The first twin wrist member 415A may include a first leg 415A1 and a second leg 415A2. A first end effector 418A may be attached to the distal end of the first leg 415A1 and the second end effector 418B may be attached to the distal end of the second leg 415A2. The second twin wrist member 415B may also include a first leg 415B1 and a second leg 415B2. A third end effector 418C may be attached to the distal end of the first leg 415B1 and a fourth end effector 418D may be attached to the distal end of the second leg 415B2.

The first and second twin wrist member 415A and 415B may be independently rotatable about axis 428 to retrieve and place substrates to and from a source location to a destination location. In some embodiments, each of the twin wrist members 415A and 415B can perform a dual GET and PUT operation or a triple GET and PUT operation using the four end effectors 418A-418D attached to each leg of the twin wrist members 415A and 415B. In another embodiment, the twin wrist members may be attached to two different, independently rotatable forearms. Therefore, the first twin wrist member 415A and the second twin wrist member 415B may be movable about axis 424 independent of one another.

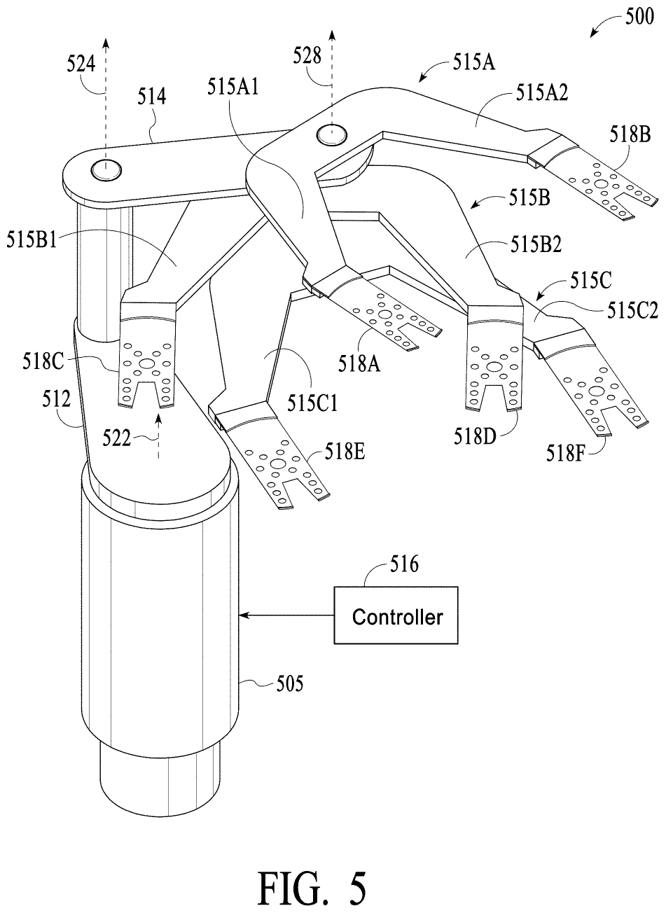

In other embodiments, the robot apparatus 400 may include additional twin wrist members (e.g., 3, 4, 5, 6, 7, etc.). For example, FIG. 5 shows a triple twin robot apparatus 500 with three twin forearm members. Robot apparatus 500 includes an arm 512 that rotates about a first rotational axis 522. A forearm 514 may be attached to a distal end of the arm 512 such that it rotates about a second rotational axis 524. Three twin wrist members 515A-515C may be attached to a distal end of the forearm 514 such that they each rotate about a third rotational axis 528. The first twin wrist member 515A may be positioned above the second twin wrist member 515B, which may be positioned above the third twin wrist member 515C. The twin wrist members 515A-515C each may be U-shaped. The first twin wrist member 515A may include a first leg 515A1 and a second leg 515A2. A first end effector 518A may be attached to the distal end of the first leg 515A1 and the second end effector 518B may be attached to the distal end of the second leg 515A2. The second twin wrist member 515B may also include a first leg 515B1 and a second leg 515B2. A third end effector 518C may be attached to the distal end of the first leg 515B1 and a fourth end effector 518D may be attached to the distal end of the second leg 515B2. The third twin wrist member 515C may also include a first leg 515C1 and a second leg 515C2. A fifth end effector 518E may be attached to the distal end of the first leg 515C1 and a sixth end effector 518F may be attached to the distal end of the second leg 515C2.

The wrist members 515A-515C may be independently rotatable about axis 528 to retrieve and place substrates to and from a source location to a destination location. In some embodiments, each of the twin wrist members 515A-515C can perform a dual GET and PUT operation, a triple GET and PUT operation, a quadruple GET and PUT operation or a quintuple GET and PUT operation using the six end effectors 518A-518F attached to each leg of the twin wrist members 515A-515C. In another embodiment, the twin wrist members may be attached to two different, independently rotatable forearms. Therefore, the twin wrist members 515A-515C may be movable about axis 524 independent of one another.

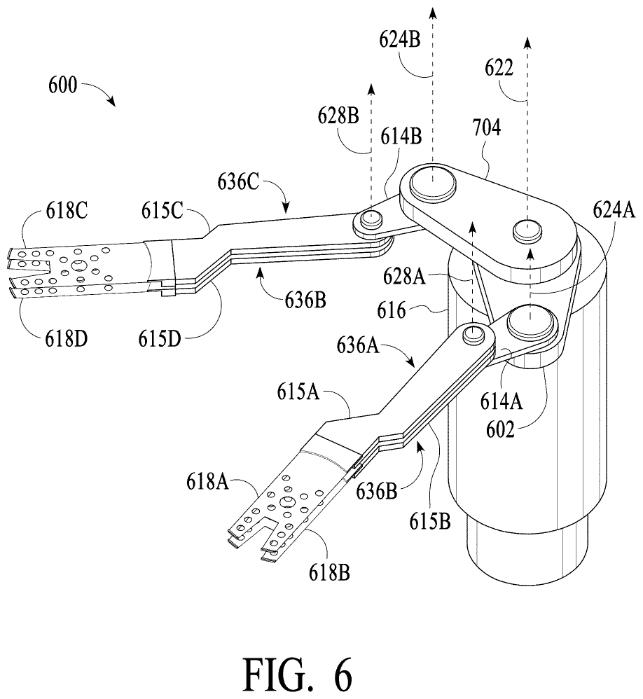

FIG. 6 depicts another example of a robot apparatus 600 for use to swap wafers in a single step. The robot 600 includes a first arm assembly 636A, a second arm assembly 636B. The first arm assembly 636A may include a first arm 612A, the second arm assembly 636B may include a second arm 612B. The first arm 612A and the second arm 612B may be substantially rigid cantilever beams including forearm drive assembly components therein. The second arm 602B is spaced vertically above the first arm 612A and they are independently rotatable about a shoulder axis 622. In another aspect, the first arm 612A and the second arm 612B may be configured and adapted to be simultaneously rotated about the shoulder axis 622 (e.g., a first axis) relative to a motor housing in clockwise and counterclockwise rotational directions. Rotation of the arms 612A-612B may be accomplished by a first motor and third motor located within the motor housing, as commanded by a controller 616. When in a fully-retracted orientation, the arm assemblies 636A-636B can be rotated to a new position along with synchronous and/or dependent rotation of a second motor. In another example, the first arm assembly and the second arm assembly can be asynchronously rotatable. For example, the movement of the first arm, and thus the first arm assembly, can be independent of the movement of the second arm and second arm assembly.

The shoulder axis 622 may be stationary in a vertical direction. This embodiment of the robot 600 may not include Z-axis capability and may be used with lift pins, moving platforms, or other like moveable substrate support structure in the process chambers 103, 106 and/or load lock chambers 109A-B (FIG. 1) to accomplish substrate exchanges. However, other embodiments of the robot 600 may include another motor and vertical drive assembly to accomplish Z-axis capability, wherein such Z-axis or vertical drive assemblies are known.

The first arm assembly 636A includes a first forearm 614A1 mounted and rotatably coupled to the first arm 612A at axis 624A. The axis 624A is spaced from the shoulder axis 622. The first forearm 614A1 is configured and adapted to be rotated in an X-Y plane relative to the first arm 612A about the second axis 624A. Rotation of the first forearm 614A1 about the second axis 624A may be dependent on the rotation of the first arm 612A about the shoulder axis 622. The first forearm 614A may be vertically located between the first arm 612A and the second arm 612B.

The second arm assembly 636A includes a second forearm 614B mounted and rotatably coupled to the second arm 612B at axis 624B. The second forearm 614B is configured and adapted to be rotated in an X-Y plane relative to the second arm 612B about the second axis 624B. Rotation of the second forearm 614B about the third axis 624B may be dependent on the rotation of the second arm 612B about the shoulder axis 622. The second forearm 614B may be vertically located between the first arm 612A and the second arm 612B.

The first forearm 614A and second forearm 614B are configured and adapted to be rotated in either a clockwise or counterclockwise rotational direction about their respective second axis 624A and third axis 624B. Rotation may be +/− about 140 degrees. Each of the forearms 614A-614B are located at different vertical locations between the first arm 612A and the second arm 612B, and do not interfere with one another when being independently rotated via rotation of the first arm 612A and/or the second arm 612B.

The first arm assembly 626A includes a first wrist member 615A mounted and rotatably coupled to the first forearm 614A at a fourth axis 628A. The fourth axis 628A is spaced from the second axis 624A. The first wrist member 615A is configured and adapted to be rotated in an X-Y plane relative to the first forearm 614A about the fourth axis 628A. Rotation of the first wrist member 615A about the fourth axis 628A may be dependent on the rotation of the first forearm 614A about the second axis 624A. The first wrist member 615A may be vertically located between the first arm 612A and the second arm 612B.

The first wrist member 615A may be coupled to a first end effector 618A. In some embodiments, the first wrist member 615A and the first end effector 618A may be integral with one another, i.e., from a same piece of material. The first end effector 618A may be configured to carry and transport substrates.

Rotation of the first wrist member 615A, and thus the first end effector 618A, may be imparted by a first wrist member drive assembly. The first wrist member 614A may be configured and adapted for rotation relative to the first forearm 614A in either a clockwise or counterclockwise rotational direction about the fourth axis 628A by the first wrist member drive assembly. Rotation may be +/− about 170 degrees. In particular, relative rotation between the first forearm 614A and the first arm 612A causes the first wrist member 615A, coupled to first end effector 618A, and supported first substrate (if present), to translate along a first path in an approximately first radial direction. Such translation may be into one of the process chambers 103, 106 as shown in FIG. 1, for example. However, it should be understood that the first wrist member drive assembly may be configured to include cammed pulleys that are configured to carry out a first path that is other than a purely radial path, such as a sweeping path.

The first arm assembly 626A also includes a second wrist member 615B mounted and rotatably coupled to the first forearm 614A at the fourth axis 628A. The second wrist member 615B is configured and adapted to be rotated in an X-Y plane relative to the first forearm 614B about the fourth axis 628A. Rotation of the second wrist member 615B about the fourth axis 628A may be dependent on the rotation of the first forearm 614A about the second axis 624A. The second wrist member 615B may be vertically located below the first wrist member 615A and between the first arm 612A and the second arm 612B.

The second wrist member 615B may be coupled to a second end effector 618B. In some embodiments, the second wrist member 615B and the second end effector 618B may be integral with one another, i.e., from a same piece of material. The second end effector 618B may be configured to carry and transport substrates.

Rotation of second wrist member 615B, and thus the second end effector 618B, may be imparted by a second wrist member drive assembly. The second wrist member 614B may be configured and adapted for rotation relative to the first forearm 614A in either a clockwise or counterclockwise rotational direction about the fourth axis 628A by the second wrist member drive assembly. Rotation may be +/− about 170 degrees. In particular, relative rotation between the first forearm 614A and the first arm 612A causes the second wrist member 615B, coupled to second end effector 618B, and a supported second substrate (if present), to translate along a second path in an approximately second radial direction. Such translation may be into one of the process chambers 103, 106 as shown in FIG. 1, for example. However, it should be understood that the second wrist member drive assembly may be configured to include cammed pulleys that are configured to carry out a second path that is other than a purely radial path, such as a sweeping path.

The second arm assembly 636B includes a third wrist member 614C mounted and rotatably coupled to the second forearm 614B at a fifth axis 628B. The fifth axis 628B is spaced from the third axis 624B. The third wrist member 615C is configured and adapted to be rotated in an X-Y plane relative to the second forearm 614B about the fifth axis 628B. Rotation of the third wrist member 615C about the fifth axis 628B may be dependent on the rotation of the second forearm 614B about the third axis 624B. The third wrist member 615C may be vertically located between the first arm 612A and the second arm 612B.

The third wrist member 615C may be coupled to a third end effector 618C. In some embodiments, the third wrist member 615C and the third end effector 618C may be integral with one another, i.e., from a same piece of material. The third end effector 618C may be configured to carry and transport substrates.

Translation of the third wrist member 615C, and thus the third end effector 618C and supported substrate (if present), may be imparted by a third wrist member drive assembly. The third wrist member 615C is configured and adapted for rotation relative to the second forearm 614B in either a clockwise or a counterclockwise rotational direction about the fifth axis 628B by the third wrist member drive assembly. Rotation may be +/− about 170 degrees. In particular, relative rotation between the second forearm 614B and the second arm 612B can cause the third wrist member 615C and coupled third end effector 618C as well as the supported substrate (if present) to translate substantially radially along a third path. Such translation may be into one of the process chambers 103, 106 as shown in FIG. 1, for example. In another example, the process chambers 103, 106 can be configured radially about the robot apparatus 600, rather than rectangular as depicted in FIG. 1. However, it should be understood that the third wrist member drive assembly may be configured to include cammed pulleys to carry out a third path that is other than purely radial.

The second arm assembly 636B also includes a fourth wrist member 614D mounted and rotatably coupled to the second forearm 614B at a fifth axis 628B. The fourth wrist member 615D is configured and adapted to be rotated in an X-Y plane relative to the fourth forearm 614D about the fifth axis 628B. Rotation of the fourth wrist member 615D about the fifth axis 628B may be dependent on the rotation of the second forearm 614D about the third axis 624B. The fourth wrist member 615D may be vertically located below the third wrist member 615C and between the first arm 612A and the second arm 612B.

The fourth wrist member 615D may be coupled to a fourth end effector 618D. In some embodiments, the fourth wrist member 615D and the fourth end effector 618D may be integral with one another, i.e., from a same piece of material. The fourth end effector 618D may be configured to carry and transport substrates.

Translation of the fourth wrist member 615D, and thus the fourth end effector 618D and supported substrate (if present), may be imparted by a fourth wrist member drive assembly. The fourth wrist member 615D is configured and adapted for rotation relative to the second forearm 614B in either a clockwise or a counterclockwise rotational direction about the fifth axis 628B by the fourth wrist member drive assembly. Rotation may be +/− about 170 degrees. In particular, relative rotation between the second forearm 614B and the second arm 612B can cause the fourth wrist member 615D and coupled fourth end effector 618D as well as the supported substrate (if present) to translate substantially radially along a fourth path. Such translation may be into one of the process chambers 103, 106 as shown in FIG. 1, for example. In another example, the process chambers 103, 106 can be configured radially about the robot apparatus 600, rather than rectangular as depicted in FIG. 1. However, it should be understood that the fourth wrist member drive assembly may be configured to include cammed pulleys to carry out a fourth path that is other than purely radial.

The forearms 614A, 614B and wrist members 615A-615D are all received between the vertical locations of the first arm 612A and the second arm 612B. Furthermore, the first arm 612A, first forearm 614A and first and second wrist members 615A, 615B are all arranged below the locations of the second arm 612B, second forearm 614B and third and fourth wrist members 615C-615D, so that interference is avoided for all rotational conditions.

In one or more embodiments, the first arm 612A and the first forearm 614A may be of unequal lengths. For example, a length L21 between the shoulder axis 622 and the second axis 624A on the first arm 612A may be greater than a length L22 between the second axis 624A and the fourth axis 628A on the first forearm 614A. The second arm 612B and second forearm 614B may also be of unequal lengths. For example, a length L23 between the shoulder axis 622 and the third axis 624B on the second arm 612B may be greater than a length L24 between the third axis 624B and the fifth axis 628B on the second forearm 614B.

In some embodiments, the lengths L21 and L23 of the first arm 612A and the second arm 612B may be between about 110% and 200% greater than the lengths L22 and L24 of the first forearm 614A and second forearm 614B, respectively. In one or more embodiments, the lengths L21 and L23 of the first arm 612A and the second arm 612B may be between about 200 mm and about 380 mm. The lengths L22 and L24 of the first forearm 614A and the second forearm 614B may be between about 100 mm and 345 mm. The second forearm 614B may be a mirror image of the first forearm 614A.

In the depicted embodiment, the first forearm 614A may include a first wrist member drive assembly. The first wrist member drive assembly includes a first wrist member driving member, which comprises a cam surface and a first wrist member driven member connected by a first wrist member transmission element made up of multiple belts. The first wrist member driving member may be an oblong pulley including a cam surface. The first wrist member driving member may be rigidly coupled to the first arm 612A, such as by a shaft or by direct connection. Other types of rigid connections may be used. Likewise, the first wrist member driven member may be an oblong pulley including a cam surface and may be rigidly connected to the first wrist member 615A.

The first forearm 614 may further include a second wrist member drive assembly including a second wrist member driving member. The second wrist member driving member may include a cam surface and a second wrist member driven member connected by ta second wrist member transmission element made up of multiple belts. The second wrist member driving member may be an oblong pulley including a cam surface. The second wrist member driving member may be rigidly coupled to the first arm 612A, such as by a shaft or by direct connection. Other types of rigid connections may be used. Likewise, the second wrist member driven member may be an oblong pulley including a cam surface and may be rigidly connected to the second wrist member 615B.

In the depicted embodiment, the second forearm 614B may include a third wrist member drive assembly. The third wrist member drive assembly includes a third wrist member driving member, which comprises a cam surface and a third wrist member driven member connected by a third wrist member transmission element made up of multiple belts. The third wrist member driving member may be an oblong pulley including a cam surface. The third wrist member driving member may be rigidly coupled to the second arm 612B, such as by a shaft or by direct connection. Other types of rigid connections may be used. Likewise, the third wrist member driven member may be an oblong pulley including a cam surface and may be rigidly connected to the third wrist member 615C.

The second forearm 614B may further include a fourth wrist member drive assembly. The fourth wrist member drive assembly includes a fourth wrist member driving member, which comprises a cam surface and a fourth wrist member driven member connected by a fourth wrist member transmission element made up of multiple belts. The fourth wrist member driving member may be an oblong pulley including a cam surface. The fourth wrist member driving member may be rigidly coupled to the second arm 612B, such as by a shaft or by direct connection. Other types of rigid connections may be used. Likewise, the fourth wrist member driven member may be an oblong pulley including a cam surface and may be rigidly connected to the fourth wrist member 615D.

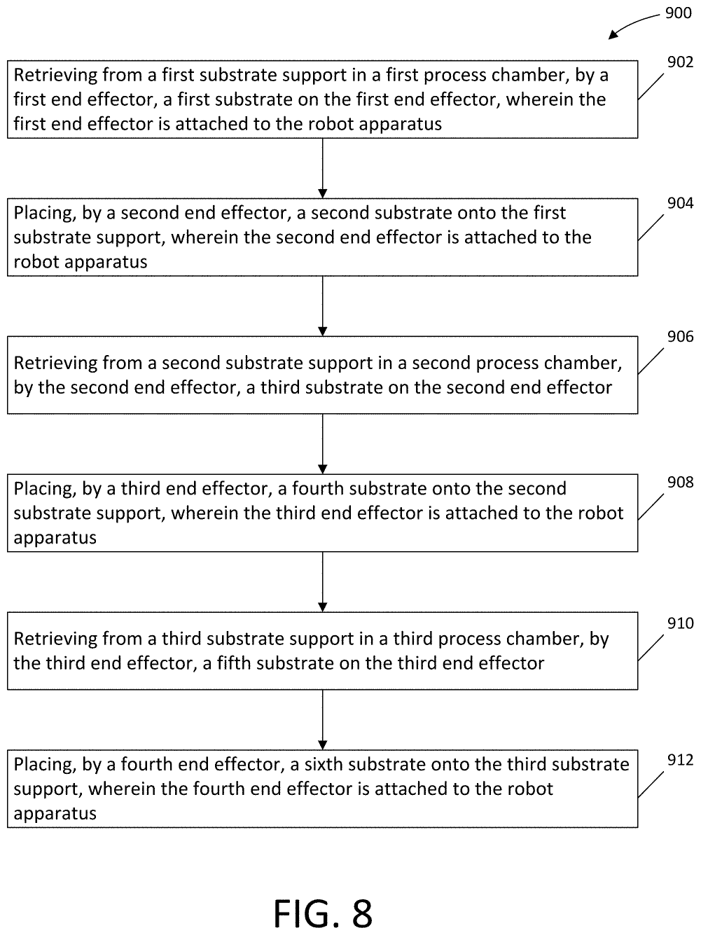

Referring now to FIG. 8A, a method 800 of transporting substrates to and from at least one process chamber containing N substrate supports (where N is >2) is described. Method 800 may be performed using any of the robot apparatuses described in embodiments above for example. In embodiments, the robot apparatus includes at least N+1 end effectors. Each end effector may be attached to a distal end of a corresponding forearm or two end effectors may be attached to a distal end of legs of a single forearm. In embodiments, if N=3, the robot apparatus may have four forearms or four arms, each having one end effector attached thereto. Method 800 may be performed by a robot apparatus including N+1 end effectors, where N of those end effectors hold substrates to be placed into a processing chamber (e.g., unprocessed substrates).

The method 800 includes, at block 802, retrieving from a first substrate support (e.g., of a first process chamber), by a first end effector (the empty end effector), a first substrate on the first end effector, wherein the first end effector is attached to the robot apparatus. The method 800 includes, at block 804, placing, by a second end effector, a second substrate onto the first substrate support, wherein the second end effector is attached to the robot apparatus.

The method 800 includes, at block 806, retrieving from a second substrate support (e.g., of the first process chamber or of a second process chamber), by the second end effector, a third substrate on the second end effector. The method 800 includes, at block 808, placing, by a third end effector, a fourth substrate onto the second substrate support, wherein the third end effector is attached to the robot apparatus.

The method 800 includes, at block 810, retrieving from a third substrate support (e.g., of the first process chamber, the second process chamber, or a third process chamber), by the third end effector, a fifth substrate on the third end effector. The method 800 includes, at block 812, placing, by a fourth end effector, a sixth substrate onto the third substrate support, wherein the fourth end effector is attached to the robot apparatus.

As a result of the retrieving and the placing, the second, fourth and sixth substrates are placed in the process chamber, the first, second and third end effectors each hold one of the three processed substrates, and the fourth end effector is empty. After the processed substrates have been removed from the process chamber and are held on the end effectors, they may be placed into a load lock or other process chamber. If N was greater than 3, then additional put and pick operations would be performed to alternately retrieve a next processed wafer from the process chamber(s) and to place a next unprocessed wafer into the process chamber(s). This cycle is repeated until all N processed substrates have been removed from the one or more process chambers and N unprocessed substrates have been placed into the one or more process chambers. Thus if N=4, then there are four pick operations and four put operations performed. If N=5, then there are five pick operations and five put operations performed.

In one embodiment, the robot apparatus sequentially retrieves unprocessed substrates and places processed substrates in the load lock containing at least N substrate supports. In embodiments, first, second and third end effectors may simultaneously place the processed substrates in a load lock designated for loading only and may retrieve unprocessed substrates for a load lock designated for unloading only.

Referring now to FIG. 8B, a method 801 of transporting substrates to and from at least one process chamber containing N substrate supports (where N=4), for example, as in FIG. 1B, is described. Method 801 may be performed using any of the robot apparatuses described in embodiments above for example. In embodiments, the robot apparatus includes at least N+2 end effectors. Each end effector may be attached to a distal end of a corresponding arm, forearm or wrist linkage of a robot apparatus. In embodiments, the robot apparatus has three forearms or three arms, each having two blades attached thereto (N+2) in a triple twin configuration.

The method 801 includes, at block 803, retrieving (e.g., simultaneously or in parallel) from a first substrate support and a second substrate support, by a first end effector and a second end effector, respectively, a first substrate on the first end effector and a second substrate on the second end effector, wherein the first end effector and the second end effector are attached to the robot apparatus. The method 801 includes, at block 805, placing (e.g., simultaneously or in parallel), by a third end effector and a fourth end effector, a third substrate and a fourth substrate onto the first substrate support and the second substrate support (respectively), wherein the third end effector and the fourth end effector are attached to the robot apparatus.

The method 801 includes, at block 807, retrieving from a third substrate support and a fourth substrate support in the process chamber, by the third end effector and the fourth end effector (respectively), a fifth substrate on the third end effector and a sixth substrate on the fourth end effector. The method 801 includes, at block 809, placing, by a fifth end effector and a sixth end effector, a seventh substrate onto the third substrate support and an eighth substrate onto the fourth substrate support, wherein the fifth end effector and the sixth end effector are attached to the robot apparatus.

As a result of the retrieving and the placing, the third, fourth, seventh and eighth substrates are placed in the process chamber, the first, second, third and fourth end effectors each hold one of the four processed substrates, and the fifth and sixth end effectors are empty. After the processed substrates have been removed from the process chamber and are held on the end effectors, they may be placed into a load lock or other process chamber. In one embodiment, the first and second end effectors simultaneously or in parallel place the processed substrates in a load lock and may retrieve unprocessed substrates from a load lock, and the fifth and sixth end effectors simultaneously or in parallel place the processed substrates in the load lock and may retrieve unprocessed substrates from a load lock. Method 801 is discussed for a manufacturing system including N substrate supports to be handled as a unit, and with a robot arm having N+2 end effectors (e.g., from a triple twin robot apparatus), where N=4. However, in embodiments method 801 may also be performed to handle N=6, where there are N+2 end effectors (e.g., from a quadruple twin robot apparatus). In such an embodiment, additional operations would be performed after block 809 to pick up a ninth and tenth processed substrate, and then to place an eleventh and twelfth unprocessed substrate.

Referring now to FIG. 9, a method 900 of transporting substrates to and from process chambers within a system is described. Each process chamber 103 may contain only one substrate support as shown in FIG. 1A. In embodiments, the total number N of substrates in the system 100 may be 3, 4, 5, 6 and so on. The robot apparatus 102 may have N+1 end effectors or 4, 5, 6, 7 and so on end effectors. The robot apparatus of method 900 may be any of the robot apparatuses described in embodiments above for example.

The method 900 includes, at block 902, retrieving from a first substrate support in a first process chamber 103, by a first end effector (i.e., that is empty), a first substrate (i.e., a processed substrate) on the first end effector. In embodiments, the first end effector and first substrate may move out of the first process chamber and a second end effector carrying a second substrate (e.g., unprocessed substrate) may move into the process chamber. At block 904, the method 900 includes placing, by the second end effector, the second substrate onto the first substrate support.

At block 906, the method 900 includes retrieving, from a second substrate support in a second process chamber, by the second end effector, a third substrate on the second end effector. After placing the second substrate on the first substrate support, the robot moves the second end effector to the second process chamber to retrieve the third substrate. The second end effector may then move out of the second process chamber and the third end effector may move into the second process chamber. At block 908, the method 900 includes placing, by the third end effector, a fourth substrate onto the second substrate support.

At block 910, the method 900 includes retrieving from a third substrate support in a third process chamber, by the third end effector, a fifth substrate on the third end effector. The third end effector may move out of the second process chamber and into the third process chamber to retrieve the fifth substrate. At block 912, the method 900 includes placing, by a fourth end effector, a sixth substrate onto the third substrate support. As a result of the retrieving and the placing, the first, third and fifth (unprocessed) substrates are each placed in the three process chambers, the first, second and third end effectors each hold one of the three processed substrates, and the fourth end effector is empty. After the processed substrates have been removed from the process chamber and are held on the end effectors, they may be placed into a load lock or other process chamber according to various embodiments as described herein.

Systems, robot apparatuses and methods disclosed herein can increase throughput and efficiency over electronic device manufacturing systems, robots and methods known in the art. For example, a known put and get sequence that is carried out by a known robot apparatus to unload a set of four processed wafers from a quad process chamber and to load the quad process chamber with four unprocessed wafers is as follows:
Dual GET from a load lock by first and second end effectors (2 substrates picked up) (6.8 sec)
Rotate to Chamber (5 sec)
Dual GET from process chamber by third and fourth end effectors (7.2 sec)
Dual PUT to process chamber by the first and second end effectors (2 substrates placed on two substrate holders) (7.2 sec)
Chamber spindle rotates 180 degrees (0 sec)
Rotate to load lock (5 sec)
Dual PUT to load lock by third and fourth end effectors (6.8 sec)
Dual GET from load lock by first and second end effectors (6.8 sec)
Rotate to Chamber (5.0 sec)
Dual GET from process chamber by third and fourth end effectors (7.2 sec)
Dual PUT to process chamber by first and second end effectors (7.2 sec)
Rotate to load lock (5 sec)
Dual PUT to load lock by third and fourth end effectors (6.8 sec)
Total time: 76 sec=>189.47 substrates per hour

In comparison, a suitable put and get sequence that is carried out by a triple twin yaw robot apparatus as shown in FIGS. 1B and 4 to unload a set of four processed wafers from a quad process chamber and to load the quad process chamber with four unprocessed wafers is as follows:
Dual GET from a load lock by first and second end effectors (2 substrates picked up) (6.8 sec)
Dual GET from the load lock by third and fourth end effectors (2 substrates picked up) (6.8 sec)
Rotate to Chamber (5 sec)
Dual GET from process chamber with fifth and sixth end effectors (7.2 sec)
Dual PUT to process chamber with third and fourth end effectors (7.2 sec)
Dual GET from process chamber with third and fourth end effectors (7.2 sec)
Dual PUT to process chamber with first and second end effectors (7.2 sec)
Rotate to load lock (5 sec)
Dual PUT to process chamber with fifth and sixth end effectors (6.8 sec)
Dual PUT to process chamber with third and fourth end effectors (6.8 sec)
Total time: 56 sec=>257.14 substrates per hour.

As shown in this example, providing a robot apparatus having at least N+1 or N+2 end effectors according to embodiments herein can eliminate sequence steps requiring a return to the load lock. Enabling the robot apparatus to completely swap processed substrates with unprocessed substrates in a single cycle can significantly improve efficiency and substrate throughput of electronic device processing systems. In embodiments, further productivity improvements are possible if simultaneous gets/puts are completed at the load lock for all four (4) substrates.

The foregoing description discloses only certain example embodiments. For example, certain example embodiments describe two stacked end effectors. Modifications of the above-disclosed systems, apparatus, and methods which fall within the scope of the disclosure will be readily apparent to those of ordinary skill in the art. For example, embodiments discussed with reference to two stacked end effectors also apply to three, four or more stacked end effectors. Additionally, embodiments are not limited to the robots, process chamber architectures or transfer chamber architectures illustrated and described herein. Accordingly, while the present disclosure has been disclosed in connection with certain example embodiments, it should be understood that other embodiments may fall within the scope of the disclosure, as defined by the following claims.

What is claims is:

1. A system, comprising:
one or more process chambers collectively or individually comprising N substrate supports, wherein N is an integer greater than or equal to 2;
at least one load lock; and
a robot apparatus configured to transport substrates between the at least one load lock and the at least one process chamber, the robot apparatus comprising at least N+1 end effectors configured to transport the substrates.

2. The system of claim 1, wherein the robot apparatus further comprises:
a first arm rotatable about a first shoulder axis;
a first forearm rotatable relative to the first arm about a first forearm axis at a position offset from the shoulder axis;
a first end effector of the at least N+1 end effectors attached to a distal end of the first forearm;
a second forearm rotatable relative to the first arm about the first forearm axis;
a second end effector of the at least N+1 end effectors attached to the distal end of the second forearm;
a third forearm rotatable relative to the first arm about the first forearm axis; and
a third end effector of the at least N+1 end effectors attached to the distal end of the third forearm.

3. The system of claim 2, wherein the robot apparatus further comprises:
a fourth forearm rotatable relative to the first arm about the first forearm axis;
a fourth end effector of the at least N+1 end effectors attached to the distal end of the fourth forearm; and
optionally, a fifth forearm rotatable relative to the first arm about the first forearm axis and a fifth end effector of the at least N+1 end effectors attached to the distal end of the fifth forearm.

4. The system of claim 2, wherein the first, second and third forearm are each independently rotatable about the first forearm axis.

5. The system of claim 1, comprising a plurality of process chambers, each process chamber comprising fewer than N substrate supports, wherein in combination the fewer than N substrate supports of the plurality of process chambers is equal to N.

6. The system of claim 1, comprising four (4) process chambers, each process chamber comprising one substrate support, wherein N=4.

7. The system of claim 1, comprising six (6) process chambers, each process chamber comprising one substrate support or one (1), wherein N=6.

8. The system of claim 1, wherein the one or more process chambers each comprises N substrate supports.

9. The system of claim 1, further comprising:
one or more vias in the one or more process chambers, the transfer chamber, or an additional chamber connected to the transfer chamber.

10. A system, comprising:
at least one process chamber comprising a plurality of substrate supports, wherein the total number of substrate supports within the at least one process chamber is N, wherein N is an even integer greater than or equal to 2;
at least one load lock; and
a robot apparatus configured to transport substrates between the at least one load lock and the at least one process chamber, the robot apparatus comprising at least N+2 end effectors configured to transport the substrates.

11. The system of claim 10, wherein the robot apparatus comprises:
an arm rotatable about a shoulder axis;
a forearm rotatable relative to the arm about a forearm axis at a position offset from the shoulder axis;
a first wrist member rotatable relative to the forearm about a wrist axis at a position offset from the forearm axis, wherein the first wrist member comprises a first end effector and a second end effector of the at least N+2 end effectors attached to distal ends of the first wrist member, wherein the first end effector and the second end effector are spaced laterally apart by a first fixed position; and
a second wrist member positioned vertically below the first wrist member and rotatable relative to the forearm about the wrist axis, wherein the second wrist member comprises a third end effector and a fourth end effector of the at least N+2 end effectors attached to distal ends of the second wrist member, wherein the third end effector and the fourth end effector are spaced laterally apart at a second fixed position,
optionally, wherein each of the first to fourth end effectors comprises a substrate support location having a nominal center, wherein at a neutral resting position of the robot apparatus, the nominal center of the first and third end effectors align along a first vertical axis, and wherein the nominal center of the second and fourth end effectors align along a second vertical axis.

12. The system of claim 11, wherein the robot apparatus further comprises:
a third wrist member positioned vertically below the second wrist member and rotatable relative to the forearm about the wrist axis, wherein the third wrist member comprises a fifth end effector and a sixth end effector of the at least N+2 end effectors attached to distal ends of the third wrist member, wherein the fifth end effector and the sixth end effector are spaced laterally apart at a third fixed position, and
optionally, a fourth wrist member positioned vertically below the third wrist member and rotatable relative to the forearm about the wrist axis, wherein the fourth wrist member comprises a seventh end effector and an eighth end effector of the at least N+2 end effectors attached to distal ends of the fourth wrist member, wherein the seventh end effector and the eighth end effector are spaced laterally apart at a fourth fixed position.

13. The system of claim 12, wherein the first wrist member, second wrist member, third wrist member and fourth wrist member are independently rotatable about the wrist axis.

14. The system of claim 13, wherein each of the first to eighth end effectors comprises a substrate support location having a nominal center, wherein at a neutral resting position of the robot apparatus, the nominal center of the first, third, fifth and seventh end effectors align along a first vertical axis, and wherein the nominal center of the second, fourth, sixth and eighth end effectors align along a second vertical axis.

15. The system of claim 10, comprising at least one process chamber comprising four (4) substrate supports, wherein N=4.

16. The system of claim 1, comprising at least one process chamber comprising six (6) substrate supports, wherein N=6.

17. The system of claim 1, wherein the one or more process chambers each comprises N substrate supports.

18. A system, comprising:
at least one process chamber comprising at least one substrate support;
at least one via comprising at least one substrate support, wherein the total number of substrate supports collectively within the at least one process chamber and the at least one via is N, wherein N is an integer greater than or equal to 2;
at least one load lock; and
a robot apparatus configured to transport substrates between the at least one load lock, the at least one process chamber and the at least one via, the robot apparatus comprising at least N+1 or at least N+2 end effectors configured to transport the substrates.

19. A method of transporting substrates by a robot apparatus, comprising:
retrieving from a first substrate support, by a first end effector, a first substrate on the first end effector, wherein the first end effector is attached to the robot apparatus;
placing, by a second end effector, a second substrate onto the first substrate support, wherein the second end effector is attached to the robot apparatus;
retrieving from a second substrate support, by the second end effector, a third substrate on the second end effector;
placing, by a third end effector, a fourth substrate onto the second substrate support, wherein the third end effector is attached to the robot apparatus;
retrieving from a third substrate support, by the third end effector, a fifth substrate on the third end effector; and
placing, by a fourth end effector, a sixth substrate onto the third substrate support, wherein the fourth end effector is attached to the robot apparatus.

20. A method of transporting substrates by a robot apparatus, comprising:
retrieving from a first substrate support within a first process chamber, by a first end effector, a first substrate on the first end effector, wherein the first end effector is attached to the robot apparatus;
placing, by a second end effector, a second substrate onto the first substrate support, wherein the second end effector is attached to the robot apparatus;
retrieving from a second substrate support in a second process chamber, by the second end effector, a third substrate on the second end effector;
placing, by a third end effector, a fourth substrate onto the second substrate support, wherein the third end effector is attached to the robot apparatus;
retrieving from a third substrate support in a third process chamber, by the third end effector, a fifth substrate on the third end effector; and
placing, by a fourth end effector, a sixth substrate onto the third substrate support, wherein the fourth end effector is attached to the robot apparatus.
